(19) United States
(12) Patent Application Publication
(10) Pub. No.: US 2015/0232329 A1
(43) Pub. Date: Aug. 20, 2015

(54) Method for eutectic bonding of two carrier devices

(71) Applicant: Robert Bosch GmbH, Stuttgart (DE)

(72) Inventor: Johannes CLASSEN, Reutlingen, DE (US)

(21) Appl. No.: 14/622,567

(22) Filed: Feb. 13, 2015

(30) Foreign Application Priority Data
Feb. 17, 2014 (DE) 10 2014 202 808.6

(51) Int. Cl. B81C 1/00; B23K 1/20; B81B 7/00; B23K 1/00

(52) U.S. Cl. CPC B81C 1/0023; B23K 1/0016; B23K 1/20; B81B 7/008

(57) ABSTRACT

A method for eutectic bonding of two carrier devices, including the tasks of putting a first layer of a first bonding material on the first carrier device, putting a first layer of a second bonding material on the second carrier device, putting a second layer of the second bonding material, that is thin in relation to the first layer of the first bonding material, on the first layer of the first bonding material, and providing the eutectic bonding of the two carrier devices.

### RELATED APPLICATION INFORMATION

The present application claims priority to and the benefit of German patent application no. 10 2014 202 808.6, which was filed in Germany on Feb. 17, 2014, the disclosure of which is incorporated herein by reference.

### FIELD OF THE INVENTION

The present invention relates to a method for eutectic bonding of two carrier devices. The present invention also relates to a micromechanical component.

### BACKGROUND INFORMATION

Micromechanical sensors for measuring acceleration and rotational speed, for example, are believed to be understood and produced in mass production in the automobile and consumer field.

FIG. 1 shows a basic cross-sectional view of a conventional micromechanical inertial sensor 300. In this context, oxide layers 20 and polysilicon layers 30 are deposited and patterned on a silicon substrate 10. In a thick functional layer 40, movable micromechanical patterns 41 are provided. The buried polysilicon layer 30 is used as an electrical circuit-board conductor or as an electrode. For the protection from environmental influences and for the purpose of a hermetic encapsulation (setting a specified inside pressure in a cavity) of the sensitive patterns 41, the MEMS wafer 100 is bonded to a cap wafer 200.

Eutectic bonding is a common bonding method used for this purpose, for bonding aluminum and germanium, for example, in which, for instance, on MEMS wafer 100 an aluminum layer 50 is deposited and patterned, and on a surface of cap wafer 200 facing MEMS wafer 100 a Germanium layer 60 is deposited and patterned. The thicknesses of layers 50, 60 mentioned are configured to be in a range of about one to a few micrometers, in this context.

Wafers 100, 200 are subsequently heated to temperatures in the range of ca. 430° C. to ca. 450° C. and pressed together at a high contact pressure. When the two layers 50, 60 come into contact with each other, a eutectic melt is able to be formed, and during the cooling process, a metallic aluminum-germanium structure will be formed, using which an hermetic sealing ring around the movable MEMS patterns 41 of MEMS wafer 100, as well as electrical contacts between MEMS wafer 100 and cap wafer 200 are able to be implemented.

Relevant methods include, for example, those from US documents U.S. Pat. No. 5,693,574 A, U.S. Pat. No. 6,199,748 B1, U.S. Pat. No. 7,442,570 B2, U.S. Pat. No. 8,084,332 B2, US 2012 0094435 A1, German document DE 10 2007 048 604 A1 and from Bao Vu, Paul M. Zavracky, “Patterned eutectic bonding with Al/Ge thin films for microelectromechanical systems”, J. Vac. Sci. Technol. vol. 14, pp. 2588-2594 (1996).

In order for the eutectic bonding process to function reliably, the participating surfaces have to be sufficiently even and clean, as well as having sufficient pressure and sufficient temperature applied to them. It is true, however, that several effects are able to impair the homogeneity and the reliability of the bonding process:
At contact with air, both germanium and aluminum form oxidized surface areas which are able to impair bonding adhesion.
Both surfaces of bonding materials aluminum and germanium have a certain basic roughness, by which an effective geometrical contact area between the two surfaces is reduced, first of all, so that even the interdiffusion of germanium and aluminum required for the bonding process is limited. The effective contact surface may be increased by increasing the mechanical bonding pressure with which the wafers are being pressed together. However, too high a bonding pressure may lead disadvantageously to damage in the wafer structure.
Particularly for acceleration sensors, frequently so-called anti-striction coatings (ASC) or antiadhesive layers are deposited on the sensor patterns. In an undesired manner, these ASC layers also deposit on the bonding frame, and may also lead to a clearly reduced bonding adhesion. To improve the bonding adhesion, the ASC layers therefore have to be removed again, if possible, before the bonding. In the case of ASC layers on aluminum, this may usually be done by heating the wafer to a suitable temperature and for a suitable time, since the adhesion of the antiadhesive layer to aluminum is weaker than to silicon-MEMS patterns (see, for example, US 2012 0244677 A1).
However, on germanium layers, a corresponding cooling-down process is not possible, since the ASC layer there adheres similarly well as on silicon. Therefore, germanium-coated wafers require other cleaning methods, such as local heating, e.g. local heating using lasers, in which only the bonding frame is heated, or sputtering the surface. These and other cleaning methods involve some risks, however, and lead to additional costs, as a rule.

Methods are also believed to be understood concerning so-called “vertical integration” or “hybrid integration” or “3D integration”, in which at least one MEMS wafer and one evaluation ASIC wafer are connected to each other mechanically and electrically via a wafer bonding method.

Such methods are discussed, for example, in U.S. Pat. No. 7,250,353 B2, U.S. Pat. No. 7,442,570 B2, US 2010 0109102 A1, US 2011 0049652 A1, US 2011 0012247 A1, US 2012 0049299 A1, DE 10 2007 048604 A1.

These vertical integration methods are particularly desirable in combination with electrical through contacting (through-silicon vias, TSV's) and flip-chip technologies, whereby the external contacting may take place as so-called “bare die” module or “chip-scale package”, that is, without plastic packaging. Such systems are known, for example, from US 2012 0049299 A1 and US 2012 0235251 A1.

German patent document DE 10 2009 002 363 A1 discusses a eutectic bonding method in which locally configured bonding contacts are implemented via prepatterned surfaces. Based on relatively small sizes of contact areas, a pressure used in bonding is to be increased, and because of the increased pressure, a deformation and a flow speed of the molten materials of the bonding layers are supposed to be increased.

Ultimately, using the reduced contact surfaces, a good mixing of the molten materials of the two bonding layers is supposed to be made possible.

### SUMMARY OF THE INVENTION

It is an object of the present invention to provide an improved eutectic bonding method.

The object may be attained, according to a first aspect, by a method for eutectic bonding of two carrier devices, having the steps:
a) Putting a first layer of a first bonding material on the first carrier device;
b) Putting a first layer of a second bonding material on the second carrier device;
c) Putting a second layer of the second bonding material, that is thin in relation to the first layer of the first bonding material, on the first layer of the first bonding material; and
d) the eutectic bonding of the two carrier devices.

In this way, according to the present invention, two similar bonding materials are positioned “face-to-face” in opposite directions. Therefore, liquid eutectic is able to develop early, so that, because of that, an improved homogeneity of the bonding connection is supported. Based on the fact that, even before the actual bonding, a liquid phase is formed, homogeneous contacting is supported, which also causes an improved heat transfer and an improved coalescing of the two bonding materials. A better temperature equalization is able to take place because of the more intimate contact.

In addition, the contact pressure and the duration of a thermal load during bonding may advantageously be reduced, which particularly supports the gentle manufacturing of sensor devices having an ASIC wafer. In addition, the contact pressure and the duration of a thermal load during bonding may advantageously be reduced, which is particularly suitable for the gentle manufacturing of sensor devices having an ASIC wafer. As a result, the ASIC wafer may be processed in a very gentle manner. In addition, in an advantageous manner, a single cleaning method for removing oxide layers on the surfaces of the carrier devices may be used, whereby even any possible antiadhesive layer may be more easily removed. According to a second aspect, the object is attained using a micromechanical component, having:
a first carrier device; and
a second carrier device; the two carrier devices being able to be bonded eutectically; on a bonding frame of one of the two carrier devices, as the uppermost layer, a layer of a bonding material of the bonding frame of the other carrier device being situated.

Advantageous further refinements of the method and of the component are the subject matter of the dependent claims.

One advantageous refinement of the method provides that in step c) putting a second layer of the first bonding material, that is thin in relation to the first layer of the second bonding material, on the first layer of the second bonding material be carried out. This advantageously provides an alternative layer sequence of bonding materials.

A further advantageous refinement of the method provides that the second layer of the second bonding material and the second layer of the first bonding material have a thickness of ca. 30 nm to ca. 2000 nm, which may be ca. 100 nm to ca. 500 nm. Using these specific thicknesses of the second layers of the bonding materials, one may very effectively develop a liquid eutectic even before the actual bonding. Thereby, in the bonding process, a required bonding pressure may be held low and a temperature load of the carrier devices may be held to be brief.

One further advantageous embodiment of the method provides that the first bonding material be germanium and the second bonding material be aluminum. This provides two proven bonding materials.

Additional advantageous refinements of the method provide that the first bonding material be gold and the second bonding material be silicon, or that the first bonding material be copper and the second bonding material be tin. Advantageously for the method according to the present invention, additional combinations of bonding materials are made possible thereby.

One further advantageous embodiment of the method provides that the first carrier device be a MEMS wafer and the second carrier device be an ASIC wafer. This is particularly advantageous in view of vertically integrated micromechanical components, because in this way an especially gentle treatment of the sensitive wafers used is made possible.

In the following text, the present invention is described in detail together with additional features and advantages, with the aid of several figures. In this context, all the features are the subject matter of the present invention, independently of their representation in the description or in the figures, and independently of their antecedent references in the claims. The same or functionally the same elements bear the same reference symbol. Above all, the figures are intended for basic understanding and are not necessarily shown to scale.

### BRIEF DESCRIPTION OF THE DRAWINGS

FIG. 1 shows a cross sectional view of two wafers before a conventional eutectic bonding process.

FIG. 2 shows a cross sectional view of a conventional micromechanical sensor after completed eutectic bonding of the two wafers.

FIGS. 3a and 3b show detailed views of conventional bonding frames.

FIG. 4 shows a cross sectional view of two wafers before the conventional eutectic bonding, one of the wafers having an evaluation ASIC.

FIGS. 5A, 5B, 5C and 5D show basic detailed views of the carrier devices according to the present invention.

FIG. 6 shows a first specific embodiment of a bonding system having carrier devices according to the present invention.

FIG. 7 shows a further specific embodiment of a bonding system having carrier devices according to the present invention.

FIG. 8 shows a basic sequence of a specific embodiment of the method according to the present invention.

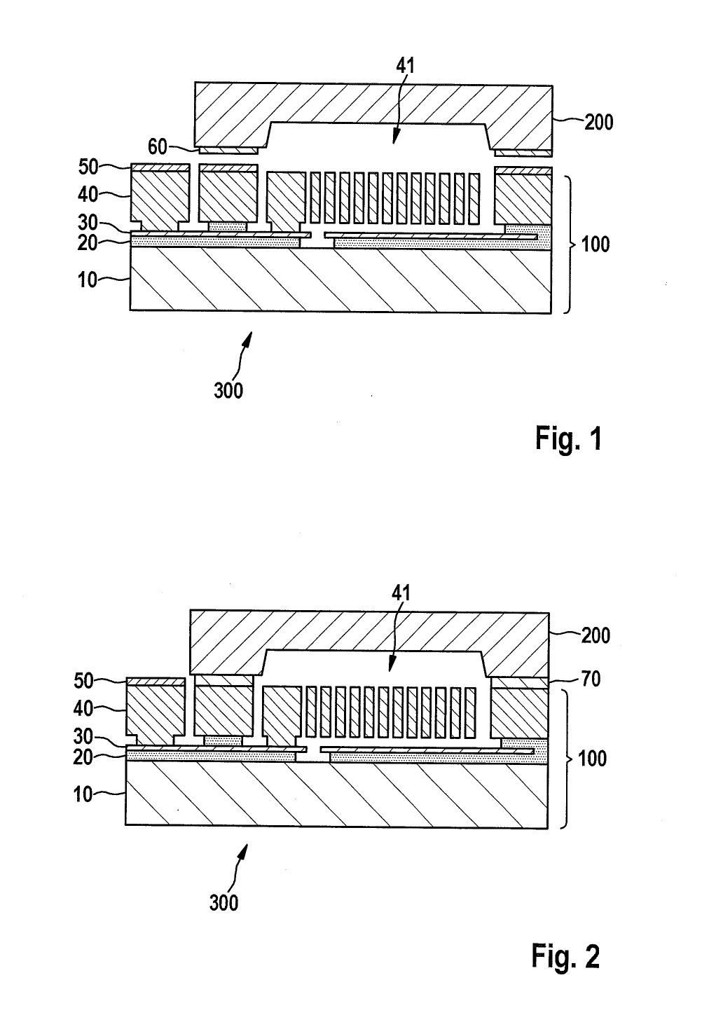

### DETAILED DESCRIPTION

FIG. 2 shows a cross sectional view of a conventional eutectically bonded micromechanical sensor element 300 having two carrier devices 100, 200. A eutectic 70 is visible, which is developed as a metallic aluminum-germanium structure. Eutectic 70 forms an hermetic sealing ring around micromechanical patterns 41 of MEMS wafer 100, as well as electrical contacts between MEMS wafer 100 and cap wafer 200, if layers 50, 60 of the two bonding materials are connected electrically conductively to thick functional layer 40 and cap wafer 200.

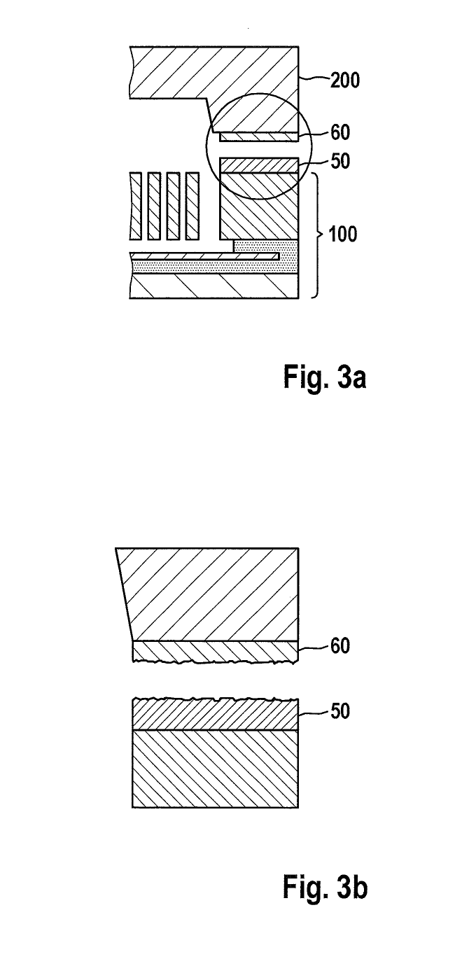

FIG. 3a shows a section, emphasized by a circular frame, of the two bonding regions having a first layer 50 of a first bonding material (e.g. aluminum) and a second layer 60 of a second bonding material (e.g. germanium). FIG. 3 shows the emphasized area of FIG. 3a basically greatly enlarged. One may see that surfaces of layers 50, 60 are able to have considerable surface roughness, and therefore permit only an incomplete, partially only point-wise developed bonding connection of the two layers 50, 60.

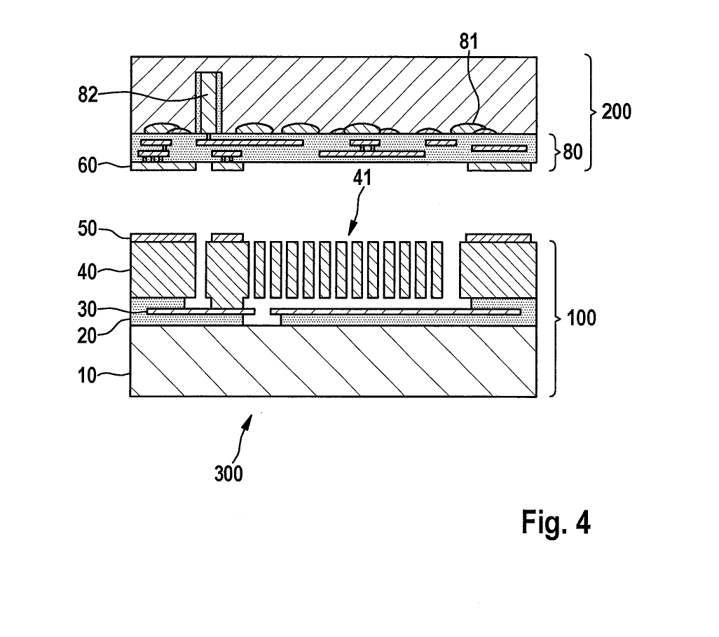

FIG. 4 shows a conventional micromechanical component 300 having a second carrier device 200 in which a metal oxide stack 80 is developed which is connected electrically conductively to a transistor area 81 and to an electrical through contacting 82 of second carrier device 200. On second carrier device 200, on a bonding frame, as an uppermost bonding area, an aluminum layer 60 is situated, which is supposed to develop an eutectic connection to a germanium layer 50 on a bonding frame of first carrier device 100.

In case MEMS wafer 100 is supposed to be vertically integrated via an eutectic aluminum-germanium bonding connection to ASIC wafer 200, there may be a risk that, based on the high mechanical bonding pressure, sensitive patterns of ASIC wafer 200, such as, especially, the transistor areas 81 or the printed circuit trace patterns of metal oxide stack 80 could be damaged and could thereby cause undesired electrical short circuits, for example. In addition, the CMOS structures are sensitive to high temperature effects above ca. 400° C. From this too, malfunctions in ASIC wafer 200 may result, particularly in the case of long-lasting increased thermal loading.

Therefore, particularly for vertically integrated MEMS components 300, it is desirable to reduce the mechanical bonding pressure and the duration of bonding, during eutectic Al—Ge bonding.

According to the present invention it is provided that one should position two equal bonding materials in opposite direction on the bonding frame of the two carrier devices 100, 200.

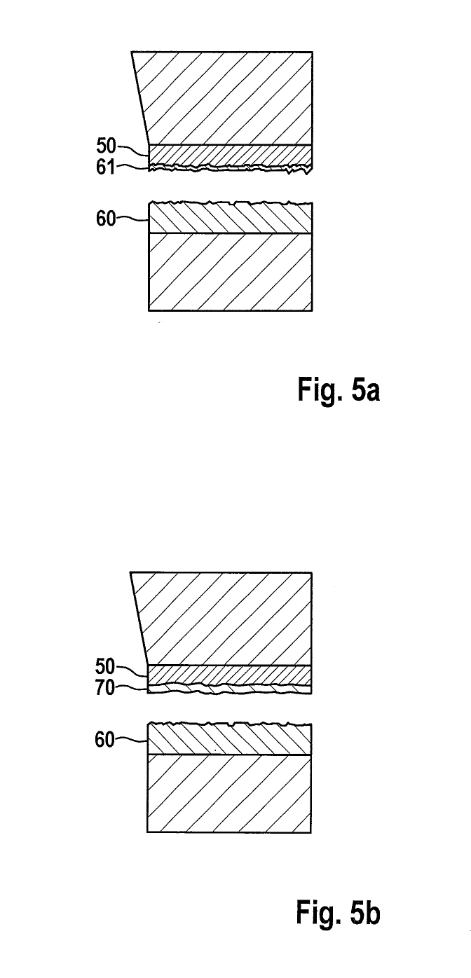

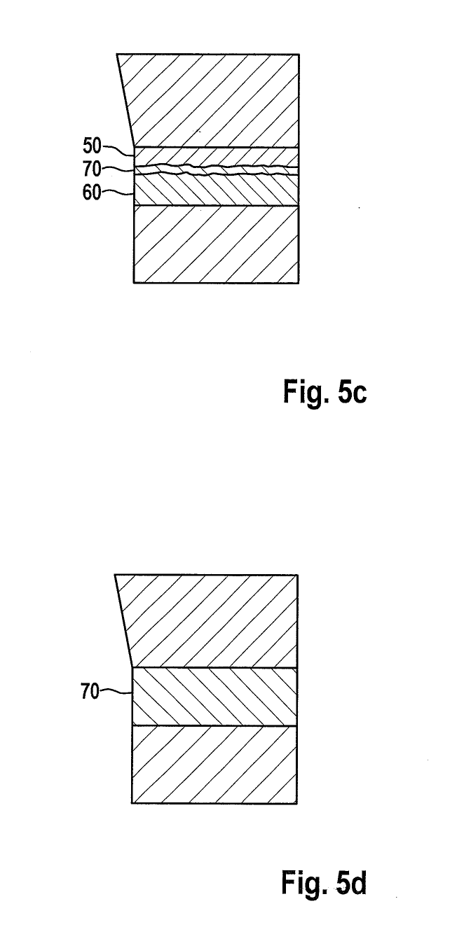

FIG. 5a shows in principle that, before the eutectic bonding of two wafers, a thin aluminum layer 61 is deposited, in addition, on germanium layer 50 of the upper wafer, and that the former is developed to be relatively thin in relation to bonding layers 50, 60, which have a thickness in the range of ca. 0.5 μm up to a few μm. For example, the thickness of additional Al layer 61 amounts to between ca. 30 nm and ca. 2000 nm, which may be between ca. 100 nm and ca. 500 nm. Consequently, stoichiometric mixture relationships of the eutectic melt are expected to be achieved using predefined layer thicknesses. This has the effect that, in the case of an increase in the temperature of the wafer to values above the eutectic point, i.e. at ca. 430° C. to 450° C. on the surface of the upper wafer, a eutectic 70 in the form of a liquid aluminum-germanium phase is formed, as shown basically in FIG. 5b.

It may be provided not to increase the temperature at first, and then to bring the upper part into contact with the lower wafer, but rather first to make mechanical contact of the two wafers and only then to run up the temperature.

When the eutectic point is exceeded, the liquid phase will now develop at the surface of the upper wafer, since there the contact between aluminum and germanium is developed in a planar manner, as shown in FIG. 5c. Since the eutectic liquid formed in such a way may easily run the wrong way, instead of the point-shaped contacts (as indicated in FIG. 3b) there now forms a substantially flatter contact between the two wafers, whereby a good equalization of topographies at the surfaces, a better heat flow between the wafers but, above all, a clearly improved interdiffusion between bonding partners germanium and aluminum is made possible.

This advantageously has the result that the entire eutectic bonding method is able to be carried out at lower contact pressure and/or a shorter duration. In this way, advantageously, the reliability of the bonding connection is able to be considerably increased. Eutectic structure 70 shown in FIG. 5d is essentially similar to that in a conventional bonding method, but may advantageously have an improved homogeneity.

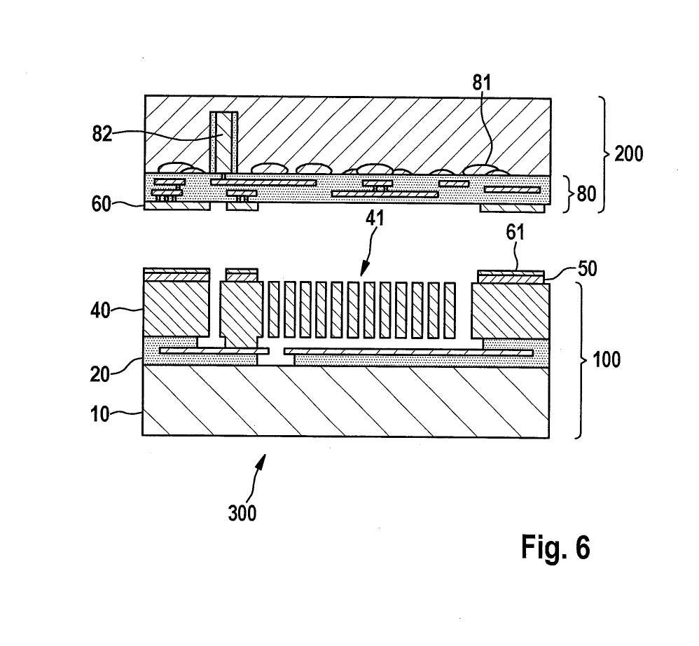

The method according to the present invention is particularly advantageously able to be carried out in combination with the vertical integration of a MEMS wafer having an ASIC wafer, as shown basically in FIG. 6. The only difference from the conventional micromechanical component 300 of FIG. 4 is that on germanium layer 50 an additional thin aluminum layer 61 is situated. For this purpose, first a germanium layer 50 is deposited on first carrier device 100 (MEMS wafer) and is patterned, and a thin aluminum layer 61 subsequently. The layer thickness of the additional thin aluminum layer 61 is developed as explained above.

Since now the surfaces of the bonding frames of both carrier devices 100, 200 are covered with aluminum, they may, in the same technical manner, be freed of oxidized material, which may be by the brief exposing of the wafer to gaseous HF or by a slight layer removal using argon sputtering. These types of cleaning are tried and tested, and may therefore contribute in a useful manner to a simplified cleaning of the surfaces of the bonding fames.

Since the uppermost layer is developed on the bonding frame of MEMS wafer 100 as an aluminum layer 61, an ASC layer (not shown) which was deposited everywhere on MEMS wafer 100, may now also be removed selectively from the bonding frame by heating wafer 100 at temperatures clearly below ca. 400° C. The ASC layer in the adhesion-sensitive silicon MEMS patterns 41 remains, in this context, advantageously unimpaired when the process is guided suitably. The selective heat reduction of the ASC layer or the antiadhesive layer of aluminum is believed to be well understood and established.

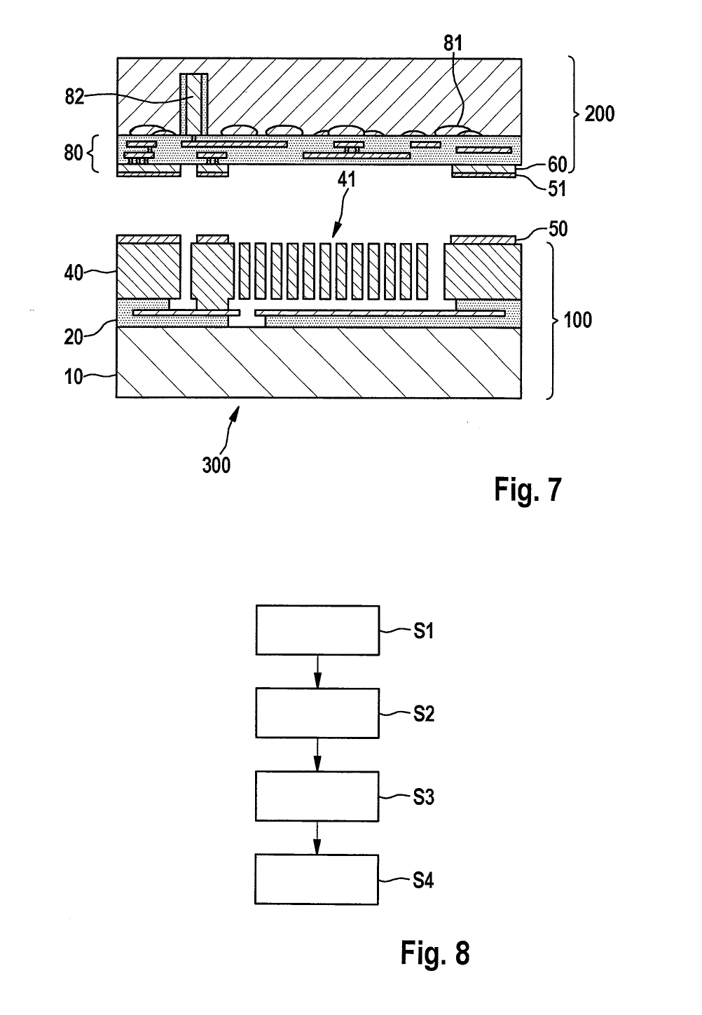

Alternatively to the system shown in FIG. 6, in a further specific embodiment of carrier devices 100, 200, as shown in FIG. 7, upper first aluminum layer 60 of ASIC wafer 200 may be covered, in the area of the bonding frame, with a thin second germanium layer 51. The argumentation with respect to the development of the eutectic melt between layers 60, 51 and the eutectic connection improved thereby and the interdiffusion is analogous to the variant explained above with the aid of FIG. 6.

It should be mentioned at this point that the advantageous properties of the invention are not limited to aluminum-germanium bonding connections, but are also transferable to other material systems and bonding partners, such as to gold-silicon systems or copper tin systems. The basic idea in each case, in the area of the bonding connection that is to be produced, to position the first material on the surface of the first wafer, and on the surface of the second wafer first to deposit a second material and then, as the uppermost layer, again a thin layer of the first material. This uppermost layer may be thinner than the layer situated below it and also thinner than the layer of the bonding material on the other wafer.

FIG. 8 shows a basic flow chart of one specific embodiment of the method of the present invention.

In a first step S1, a first layer 50 of a first bonding material is situated on the first carrier device 100.

In a step S2, a first layer 60 of a second bonding material is situated on the second carrier device 200.

In a step S3, a second layer 61 of the second bonding material, that is thin compared to first layer 50 of the first bonding material, is situated on the first layer 50 of the first bonding material.

Finally, in a step S4, a eutectic bonding is carried out of the two carrier devices 100, 200.

In summary, A method is provided using the present invention, which, with relatively low additional expenditure, enables an improved bonding connection and an improved cleaning possibility of surfaces of bonding frames. Using the method provided, which may be a vertical integration of ASIC wafers with MEMS wafers is improved because, using a decreased contact pressure during bonding and an abbreviated bonding duration, a gentle treatment of the participating wafer is supported.

Although the present invention has been described with the aid of specific exemplary embodiments, it is not limited to these. One skilled in the art, in proceeding, will thus be able to implement specific embodiments that are not described, or only partially described, without deviating from the crux of the present invention.

What is claimed is:

1. A method for eutectic bonding of a first carrier device and a second carrier device, the method comprising:
(a) putting a first layer of a first bonding material on the first carrier device;
(b) putting a first layer of a second bonding material on the second carrier device;
(c) putting a second layer of the second bonding material, that is thin in relation to the first layer of the first bonding material, on the first layer of the first bonding material; and
(d) eutectic bonding of the two carrier devices.

2. The method of claim 1, wherein in (c), a second layer of the first bonding material, that is thin in relation to the first layer of the second bonding material, is put on the first layer of the second bonding material.

3. The method of claim 1, wherein the second layer of the second bonding material and the second layer of the first bonding material have a thickness of ca. 30 to ca. 2000 nm.

4. The method of claim 1, wherein the first bonding material is germanium and the second bonding material is aluminum.

5. The method of claim 1, wherein the first bonding material is gold and the second bonding material is silicon.

6. The method of claim 1, wherein the first bonding material is copper and the second bonding material is tin.

7. The method of claim 1, wherein the first carrier device is a MEMS wafer and the second carrier device is an ASIC wafer.

8. A micromechanical component, comprising:
a first carrier device; and
a second carrier device;
wherein the two carrier devices are bondable eutectically, and
wherein on a bonding frame of one of the two carrier devices, as the uppermost layer, a layer of a bonding material of the bonding frame of the other carrier device is situated.

9. The micromechanical component of claim 8, wherein the first carrier device is a MEMS wafer and the second carrier device is an ASIC wafer.

10. The method of claim 1, wherein the second layer of the second bonding material and the second layer of the first bonding material have a thickness of ca. 100 nm to ca. 500 nm.
